(19) United States
(12) Patent Application Publication
(10) Pub. No.: US 2005/0269688 A1
(43) Pub. Date: Dec. 8, 2005

(54) Microelectromechanical systems (MEMS) devices integrated in a hermetically sealed package

(76) Inventor: Lior Shiv, Hilleroed (DK)

Correspondence Address: FISH & RICHARDSON P.C., P.O. BOX 1022, MINNEAPOLIS, MN, 55440-1022, US

(21) Appl. No.: 11/144,429

(22) Filed: Jun. 2, 2005

Related U.S. Application Data
(60) Provisional application No. 60/576,765, filed on Jun. 3, 2004.
(60) Provisional application No. 60/662,644, filed on Mar. 17, 2005.

(51) Int. Cl. H01L 23/12

(52) U.S. Cl. 257/704; 257/774

(57) ABSTRACT

A package for a MEMS device includes a semiconductor cap structure and a lid substrate that define an encapsulated area within which the MEMS device is located. Feed-through metallization hermetically seals micro-vias in the semiconductor cap structure and extends through the semiconductor cap structure to provide interconnections coupled electrically to the MEMS device and to an exterior of the semiconductor cap structure.

### CROSS-REFERENCE TO RELATED APPLICATIONS

This disclosure claims the benefit of U.S. Provisional Application Nos. 60/576,765, filed on Jun. 3, 2004, and 60/662,644, filed on Mar. 17, 2005.

### BACKGROUND

Proper packaging of optoelectronic and other micro components is important to ensure the integrity of signals to and from the micro components and often determines the overall cost of the assembly. Microelectromechanical systems (MEMS) technology, which is capable of micromachining silicon wafers or other materials with high precision, has become a promising candidate for packaging various types of micro components.

MEMS technology is able to machine hundreds of packaging components on a single silicon wafer to yield high throughput during manufacture and low-cost components. MEMS technology also offers a broad variety of etching processes, both for glass and silicon.

Examples of MEMS devices include electrostatic switches, pressure sensors, acceleration sensors and microfluids.

### SUMMARY

The present disclosure relates to packages for MEMS devices. The package includes a semiconductor cap structure and a lid substrate, which define an encapsulated area within which the MEMS device is located. Feed-through metallization hermetically seals micro-vias in the semiconductor cap structure and extends through the semiconductor cap structure to provide interconnections coupled electrically to the MEMS device and to an exterior of the semiconductor cap structure.

The invention may be used with various types of MEMS devices.

In various implementations, one or more of the following features may be present. For example, the MEMS device may include a switch having end contacts. The feed-through metallization may provide electrical interconnections coupled, respectively, to the end contacts. Signal line and ground line interconnections may be coupled electrically to a signal strip of a transmission line on an exterior of the semiconductor cap structure. Additional interconnections may be coupled to the MEMS device to enable the switch to be activated between open and closed states by applying electrical signals to conductive pads on an exterior of the package. Thus, the MEMS device may include a first state in which the end contacts for the MEMS device are not in electrical contact with one another, and a second state in which the end contacts are in electrical contact with one another to cause a short circuit so as to block a signal on the transmission line. The transmission line to which a switching function of the MEMS device is to be applied can be routed along the exterior of the package or along the board on which the package is mounted.

The MEMS device may be located, within the encapsulated area, either on the semiconductor cap structure or the lid substrate. In some cases, some parts of the MEMS device may be located on the lid substrate and other parts may be located on the semiconductor cap structure. For example, the MEMS device may include a switch having contact pads, at least one of which is located on the lid substrate. In some implementations, one or more contact pads may be located on the semiconductor cap structure.

The MEMS device may include an actuation pad wherein, during operation, electrical signals are provided from an exterior of the package to the actuation pad via feed-through metallization that hermetically seals a micro-via extending through the semiconductor cap structure. The actuation pad may be located on the semiconductor cap structure or on the lid substrate. Some implementations may include actuation pads on both the semiconductor cap structure and the lid substrate.

The package may include one or more conductive bumps between the semiconductor cap structure and the lid substrate to provide electrical interconnection for at least one of an input signal to the MEMS device, an output signal from the MEMS device or an actuation signal for the MEMS device.

In some implementations, the semiconductor cap structure may include an etch resistant layer between semiconductor layers, and the lid substrate may include a glass wafer.

Various implementations may include one or more of the following advantages. Electrical micro-vias can enable the use of surface mounted technologies (SMT), balanced RF impedance matching between a printed circuit board and the packaged MEMS device can be achieved as well. Additional cavity space may be provided within the package for device headroom. The electrical micro-vias may allow the device to be used with high power and at high frequencies. The hermetic sealing can provide particle-free encapsulation before dicing.

The details of one or more embodiments of the invention are set forth in the accompanying drawings and the description below. Other features and advantages of the invention may be apparent from the description, the drawings, and the claims.

### BRIEF DESCRIPTION OF THE DRAWINGS

FIG. 1 illustrates a cross-sectional view of a MEMS switch in a hermetic package that is mounted to a printed circuit board.

FIGS. 2, 3 and 4 illustrate cross-sectional views of other implementations of MEMS switches integrated in hermetic packages according to the invention.

FIGS. 5A and 5B illustrate cross-sectional views of a package for a MEMS device with a thinned semiconductor cap structure.

FIG. 6 illustrates a package for a MEMS device where the semiconductor cap structure and the lid substrate are directly bonded to one another.

FIG. 7 illustrates the package of FIG. 6 after thinning of the semiconductor cap structure and after mounting the package to a printed circuit board.

FIG. 8 illustrates a package for a MEMS device that is mounted to the semiconductor cap structure of the package.

### DETAILED DESCRIPTION

The present disclosure relates to MEMS devices hermetically sealed in a package. The discussion below describes a package for an electrostatic switch which may be implemented, for example, by a metal cantilever, a contact pad under the non-anchored end of the cantilever, and an actuation pad under the main part of the cantilever. However, other electrostatic switches, as well as other MEMS devices, may be packaged using the techniques described here.

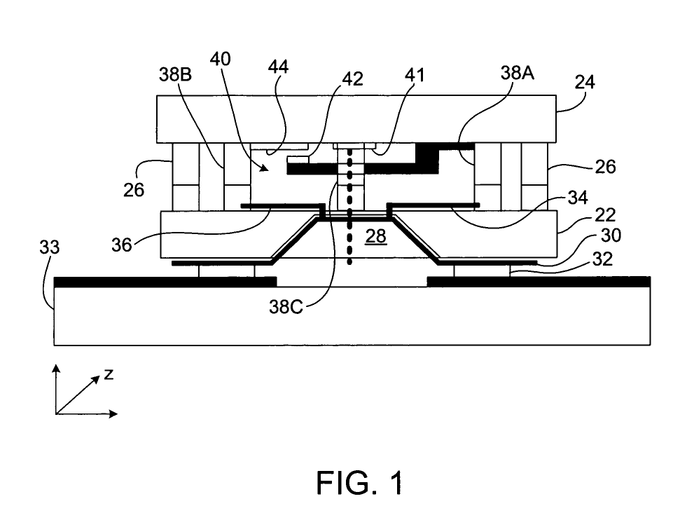

As shown in FIG. 1, a hermetically sealed package for a MEMS device includes first and second parts 22, 24. The first and second parts, which may be referred to, respectively, as a semiconductor cap structure 22 and a lid substrate 24, may be attached to one another by a sealing ring 26 to seal the MEMS device hermetically within the package and by interconnection pads 38A. 38B, 38C to form the electrical contacts between the two parts.

The lid substrate 24, which may be, for example, a glass wafer, is processed to form a MEMS switch 40. Examples of the MEMS switch include electromechanical actuators comprising cantilevers, bridges or membranes.

A transmission line 30 (e.g., a co-planar or micro-strip line) is provided on the backside of the device with pads 32 (e.g., solder bumps) for attachment to the main platform (e.g., printed circuit board or flex cables). The package may be surface-mounted, for example, to a printed circuit board 33, with the lid substrate 24 serving as a lid for the package.

Formation of the semiconductor cap structure 22 may include micro-machining to provide micro-vias on one side opposite a larger recess 28 on the front or the back of the cap structure. Feed-through metallization through some of the micro-vias in the cap 22 and along the sides of the recess 28 provides electrical interconnections 34, 36 for the signal and ground lines of the transmission line 30. The interconnections 34, 36 are coupled electrically, respectively, to end-contacts 42, 44 of the MEMS switch. The signal line interconnection(s) 34 and the ground line interconnection(s) 36 may be positioned at different locations along the z-axis, with the signal line interconnection(s) 34 coupled electrically to the signal strip of the transmission line 30. The ground line interconnection(s) 36 may be coupled electrically to the ground strip(s) of the transmission line. The end-contacts 42, 44 of the switch 40 may be routed to the electrical interconnections 34, 36 by a rigid ohmic contact (i.e., a solder bump).

Electrical signals for switching the actuator 40 may be routed from the backside of the package to an actuation pad 41 by feed-through metallization through additional micro-vias formed in the cap and metallization lines routed from the cap 22 to the actuator pad on the substrate 24. The interconnection for the actuator signal line is indicated by the dashed lines in the drawings.

In FIG. 1, both the actuation pad 41 and the contact pad 44 are on the lid substrate 24, which as mentioned above, serves as a lid for the package. Electrical interconnections to these two pads need to be routed between the cap 22 and the pads. As a result, for the implementation of FIG. 1, conductive bumps are provided between the cap and the switch for the following signals: (i) RF input to the switch (bump 38A); (ii) RF output from the switch 40 (bump 38B) and (iii) actuation signal to the switch (bump 38C). The actuator itself can be DC-grounded by the first bump 38A or by another ground contact that can be realized, for example, by the sealing ring 26.

The actuator 40 may be switched between two states. One state (i.e., the “open” state) of the switch occurs when the front edge of the first end-contact 42 is not in contact with the second end-contact 44 of the switch. The second state (i.e., the “closed” state) occurs when the first end-contact 42 is in contact with the second end-contact 44. In the closed state, the electrical contact between the two end-contacts 42, 44 of the actuator 40 causes a short-circuit between the signal and ground strips on the transmission line 30, thus blocking the signal on the transmission line 30.

Hermetic encapsulation of the MEMS device may be realized, for example, by (i) the feed-through metallization sealing the micro-vias and (ii) the solder or other sealing ring between the cap 22 and the lid substrate 24.

Although only one MEMS device is shown in the drawings, other embodiments may include two or more MEMS devices in a single package. The package may be used with a wide range of frequencies.

Formation of the Semiconductor Cap Structure and Feed-Through Metallization:

The cap 22 may comprise, for example, a semiconductor material such as silicon, so that the recess 28 can be formed by known etching processes. Various techniques may be used to form the recess 28 and the micro-vias for the feed-through metallization. One such technique uses a multilayer structure that includes a substantially etch-resistant layer sandwiched between first and second semiconductor layers. The first and second semiconductor layers may include, for example, silicon, and the etch-resistant layer may include, for example, silicon nitride, silicon oxy-nitride or silicon dioxide. The through-holes (i.e., micro-vias) may be formed using a double-sided etching process in which the first and second layers are etched until the etch-resistant layer is exposed to define the locations of the through-holes. The semiconductor layer in which the larger recess 28 is to be formed may be etched over an area that corresponds to the positions of all or a large number of the through-holes. The through-holes then may be completed by removing part of the etch-resistant layer.

The through-holes may be hermetically sealed, for example, using an electro-plated feed-through metallization process as the base for the through-hole connections.

Further details of a suitable double-sided etching and feed-through metallization process are disclosed in U.S. Pat. No. 6,818,464, which is assigned to the assignee of the present application. The disclosure of that patent is incorporated herein by reference.

Other Implementations

Various modifications may be made to the embodiment of FIG. 1. For example, the location of the actuation pad 41 and the contact pads 42, 44 may differ from that shown in FIG. 1.

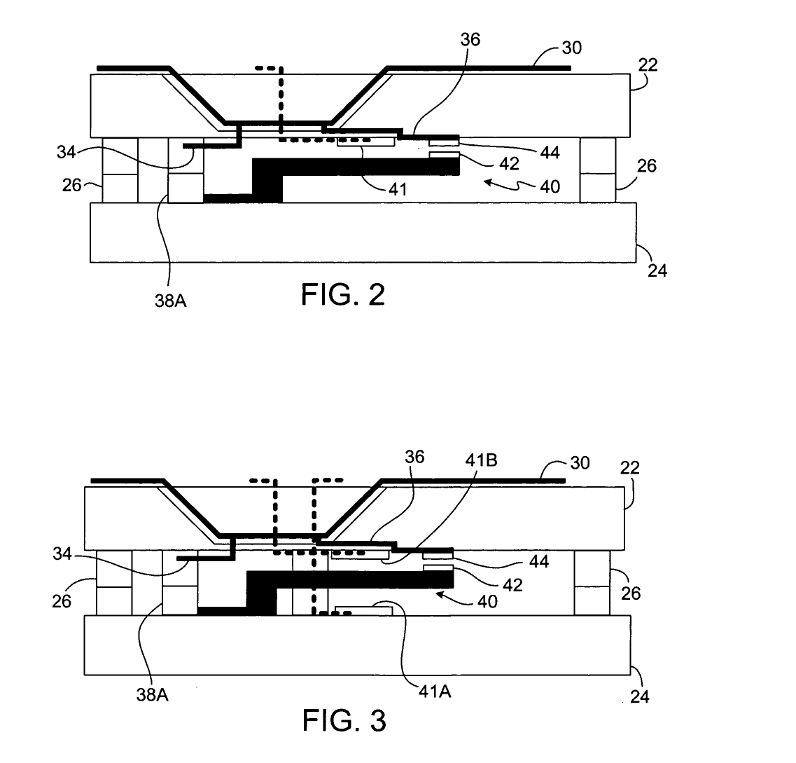

In some implementations, one or more of the contact pads may be either on the cap structure 22, on the lid substrate 24 or on both the cap structure and the lid substrate. In the latter case, the switch may function as a router with a single input and two outputs. FIG. 2 illustrates an example in which both the actuation and contact pads 41, 44 are located on the cap structure 22. FIG. 2 illustrates a package before it is assembled on the printed circuit board; therefore, the package is illustrated inverted compared to the configuration in FIG. 1.

FIG. 3 illustrates a configuration in which actuation pads 41A, 41B are arranged on both the cap structure 22 and the lid substrate 24. Thus, there is an actuation pad on either side of the switch cantilever structure.

In the embodiment of FIG. 1, both end points of the RF signal are routed through the cap structure 22 to the respective end-contacts 42, 44 of the switch 40 on the lid substrate 24. On the other hand, in the embodiment of FIG. 2, the contact pad 44 is located on the cap structure 22. Therefore, only one end-point of the RF signal is routed (through a solder bump) to the lid substrate 24.

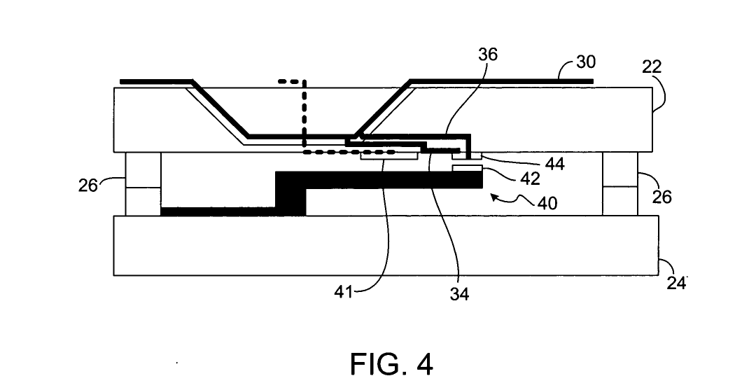

In other embodiments, both end-points of the RF signal may be located on the cap structure 22, inside the encapsulated space. An example of such a design is illustrated in FIG. 4. When the cantilever is pulled up, it contacts the two end-points of the RF line (only one pad 44 is shown in FIG. 4), thereby creating a short circuit. A second actuation pad (not shown in FIG. 4) on the lid substrate 24 may be provided as described in connection with FIG. 3.

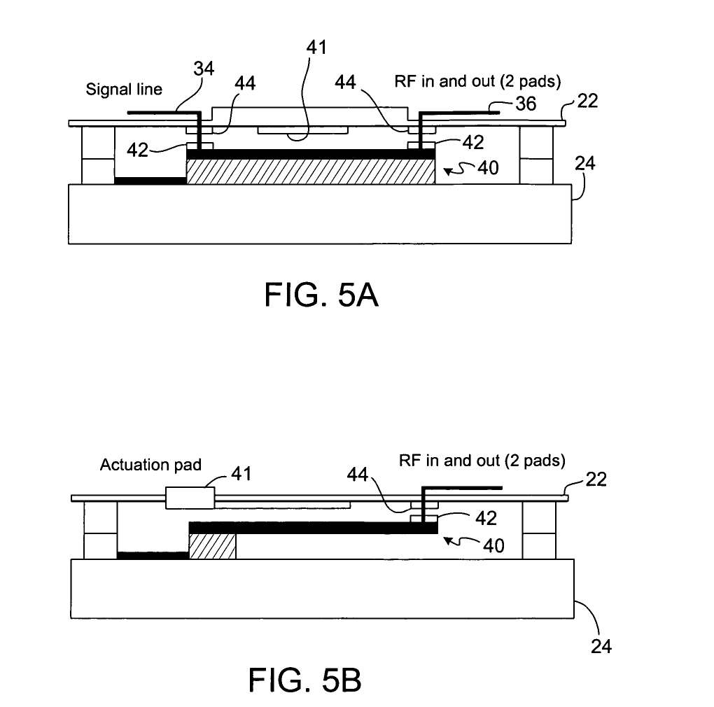

The foregoing designs can be simplified by thinning down the back-side of the cap structure 22. FIGS. 5A and 5B illustrate, respectively, front and side views for a design similar to the one described in connection with FIG. 4, except that the cap structure 22 has been thinned. For designs in which the back-side of the cap structure is thinned, the switch 40 may be positioned very close to the printed circuit board (e.g., 33 in FIG. 1). As a result, routing the RF line from the printed circuit board 33 to the back-side of the cap structure 22 and back to the board is unnecessary.

Various techniques may be used for the thinning process, including mechanical grinding or polishing techniques. Further details of such techniques are disclosed in U.S. application Ser. No. 11/082,507, filed on Mar. 17, 2005 and assigned to the assignee of the present disclosure.

In some implementations, the sealing technology of the package may be based on the use of a metal sealing ring (e.g., solder). The sealing ring also may be used to route the electrical “ground” interconnection to the cantilever of the switch 40.

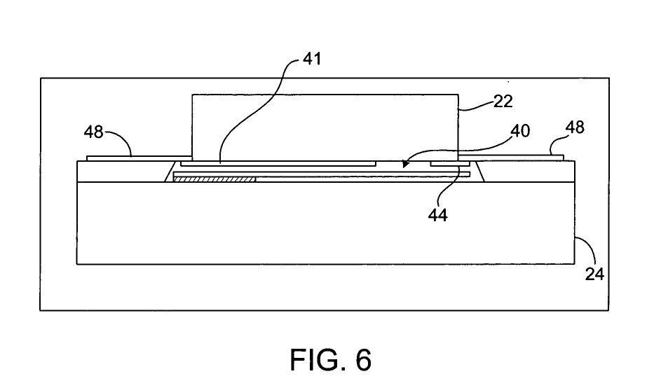

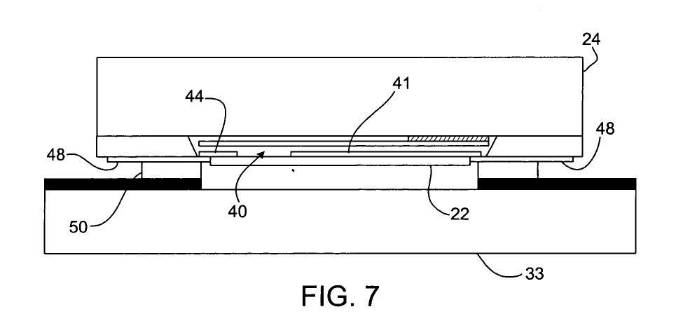

The cap structure 22 and the lid substrate 24 may be bonded, for example, by direct wafer-to-wafer bonding techniques (e.g., anodic bonding) in which a metal interface is not required for the bonding and the encapsulation. An example of such a design is illustrated in FIG. 6 in which the package is shown after bonding the two wafers 22, 24 together, but before thinning the back-side of the cap structure 22. After thinning the back-side of the cap structure 22, the package may be attached to the printed circuit board 33, as shown in FIG. 7, using back-side surface mount pads 48 and bumps 50.

In applications such as electrostatic switches in which the cantilever needs to be grounded, a metal contact between the rigid part of the cantilever and the cap can be formed by two metal stand-offs being pressed against each other during the bonding of the two wafers (see, e.g., bump 38A in FIGS. 1, 2 and 3). In other applications, such as magnetic switches, the additional contact is not required.

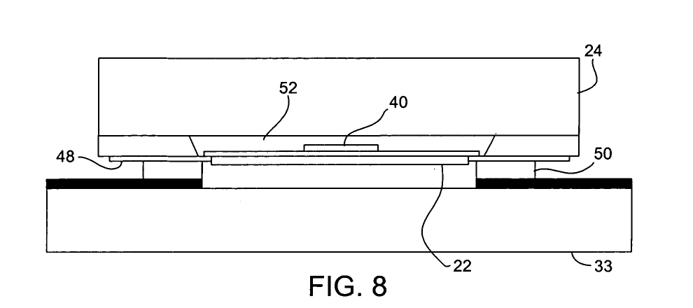

In the foregoing implementations, at least part of the switch (e.g., the cantilever) is located on the glass wafer 24 that serves as the lid of the package. However, in other implementations, all parts of the switch may be integrated into the cap structure 22 in which the electrical feed-through connections are provided, as indicated by FIG. 8. By placing the cantilever, as well as the contacts, of the MEMS switch 40 on the cap structure 22 rather than the lid substrate 24, electrical contacts to the lid substrate are not required. Headroom for the MEMS device 40 may be provided by forming a cavity 52 in the bulk material of the cap structure 22. The MEMS device 40 can be positioned in the cavity 52, which is then covered by the lid substrate 24. Alternatively, a cavity may be formed in the lid substrate to provide the headroom for the MEMS device. In some implementations, opposing cavities may be formed in both the cap structure 22 and the lid substrate 24 to provide the required headroom.

Other implementations are within the scope of the claims.

1. A package for a MEMS device, wherein the package comprises:
a semiconductor cap structure and a lid substrate defining an encapsulated area within which the MEMS device is located; and
feed-through metallization hermetically sealing micro-vias in the semiconductor cap structure and extending through the semiconductor cap structure to provide interconnections coupled, respectively, to the MEMS device, wherein the interconnections are coupled electrically to an exterior of the semiconductor cap structure.

2. The package of claim 1 wherein the MEMS device comprises a switch having end contacts and activation contact, wherein the feed-through metallization provides electrical interconnections coupled, respectively, to the end contacts and the activation contact.

3. The package of claim 2 wherein the feed-through metallization comprises:
signal line and ground line interconnections coupled electrically to signal and ground strips of a transmission line on an exterior of the semiconductor cap structure; and
one or more additional interconnections coupled to the MEMS device to enable the switch to be activated between open and closed states by applying electrical signals to conductive pads on an exterior of the package.

4. The package of claim 3 wherein the MEMS device has a first state in which the end contacts for the MEMS device are not in electrical contact with one another, and a second state in which the end contacts are in electrical contact with one another to cause a short circuit so as to block a signal on the transmission line.

5. The package of claim 4 wherein the transmission line to which a switching function of the MEMS device is to be applied is routed only along the exterior of the package or along a board on which the package is mounted.

6. The package of claim 1 wherein at least a part of the MEMS device is located on the semiconductor cap structure.

7. The package of claim 6 wherein the MEMS device comprises a switch having contact pads, at least one of which is located on the lid substrate.

8. The package of claim 7 wherein at least one of the contact pads is located on the semiconductor cap structure.

9. The package of claim 6 wherein the MEMS device comprises an actuation pad and wherein, during operation, electrical signals are provided from an exterior of the package to the actuation pad via feed-through metallization that hermetically seals a micro-via extending through the semiconductor cap structure.

10. The package of claim 9 wherein the actuation pad is located on the semiconductor cap structure.

11. The package of claim 9 wherein the actuation pad is located on the lid substrate.

12. The package of claim 9 wherein the MEMS device comprises an actuation pad on the lid substrate and an actuation pad on the semiconductor cap structure.

13. The package of claim 6 including one or more conductive bumps between the semiconductor cap structure and the lid substrate to provide electrical interconnection for at least one of an input signal to the MEMS device, an output signal from the MEMS device or an actuation signal for the MEMS device.

14. The package of claim 1 wherein the MEMS device includes an electrostatic switch comprising a metal cantilever, a contact pad under a non-anchored end of the cantilever, and an actuation pad.

15. The package of claim 1 wherein the MEMS device is hermetically sealed within the package.

16. The package of any one of claims 1-15 wherein the lid substrate comprises a glass wafer.

17. The package of claim 16 wherein the semiconductor cap structure includes an etch resistant layer between semiconductor layers.
